(19) United States
(12) Patent Application Publication
(10) Pub. No.: US 2025/0349575 A1
(43) Pub. Date: Nov. 13, 2025

(54) SEMICONDUCTOR PROCESSING CHAMBER THERMAL CONTROL

(71) Applicant: Applied Materials, Inc., Santa Clara, CA (US)

(72) Inventors: Varun Kumar Chenna, Karnataka (IN); Rony David Mathew, Karnataka (IN); Eli Mor, Boise, ID (US)

(21) Appl. No.: 18/659,771

(22) Filed: May 9, 2024

(51) Int. Cl. H01L 21/67; H01J 37/32

(52) U.S. Cl. CPC H01L 21/67248; H01J 37/32724; H01L 21/67017; H01J 2237/002; H01J 2237/2007; H01J 2237/334

(57) ABSTRACT

Semiconductor processing systems and system components are described for providing thermal control in semiconductor fabrication. One of the systems includes a processing chamber, the processing chamber comprising: a chamber volume, and a substrate support positioned within the chamber volume, the substrate support comprising one or more heating elements and a fluid path configured to circulate a heat transfer fluid within a body of the substrate support; and a flow control module configured to adjust a flow rate of the heat transfer fluid circulating through the body of the substrate support according to a processing heat load applied to the substrate by the processing chamber.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. During a processing operation, the processing environment is typically maintained within a specified temperature range.

### SUMMARY

This specification describes technologies for thermal control of a semiconductor processing chamber. A processing system, for example, a plasma-based processing system, generates a heat load within a processing region during performance of a particular process, e.g., plasma etching of a substrate held within the processing chamber. The processing chamber is maintained at a temperature within a specified operational range. During a processing operation, excess heat is added to the chamber. When idle, the processing chamber may need to be maintained at the operating temperature, for example, when idle period is brief between processing operations. To maintain the temperature within the specified range, a combination of heating elements and circulated heat transfer fluids can be used to adjust the temperature, e.g., the temperature within the chamber or the temperature of the substrate. This specification discloses technologies for maintaining the temperature of the processing chamber more efficiently.

In general, one innovative aspect of the subject matter described in this specification can be embodied in a system for semiconductor processing. The system includes a processing chamber, the processing chamber comprising: a chamber volume, and a substrate support positioned within the chamber volume, the substrate support comprising one or more heating elements and a fluid path configured to circulate a heat transfer fluid within a body of the substrate support; and a flow control module configured to adjust a flow rate of the heat transfer fluid circulating through the body of the substrate support according to a processing heat load applied to the substrate by the processing chamber.

In general, one innovative aspect of the subject matter described in this specification can be embodied in methods that include the actions of initializing a processing chamber to perform a plurality of processing operations, the initializing comprising heating the chamber to a temperature within a specified range for performing the processing operation; executing a first processing operation at a first RF energy, wherein during the first processing operation a heat transfer fluid is circulated in the chamber at a first flow rate configured to remove heat energy from the chamber; and upon completion of the first processing operation, changing an RF energy level from the first RF energy level to a second RF energy level, wherein in response to changing the RF energy level, changing the flow rate of the heat transfer fluid from a first flow rate to a second flow rate.

In general, one innovative aspect of the subject matter described in this specification can be embodied in a substrate support for a processing chamber. The substrate support includes one or more embedded electrodes configured to provide electrostatic attraction of a substrate; one or more heating elements; and one or more fluid paths configured to circulate a heat transfer fluid through the substrate support, the heat transfer fluid having a variable flow rate according to a processing mode of the processing chamber.

The subject matter described in this specification can be implemented in these and other embodiments so as to realize one or more of the following advantages. The flow rate of a heat transfer fluid in the semiconductor processing chamber can be controlled to more efficiently maintain the temperature of the processing chamber during idle or sleep modes. In particular, by reducing the flow rate during idle or sleep modes, the overall energy consumption of the processing chamber can be reduced. This overall energy savings can be realized even if the power to one or more heating elements is increased during the idle or sleep modes. In particular, with a constant flow rate, the heat transfer fluid will remove too much heat from the chamber during idle or sleep modes. The output of heating elements are increased to maintain the desired processing chamber temperature. However, this requires increased energy usage. By controlling the heat transfer fluid flow rate, less heat is removed from the chamber during idle or sleep modes meaning that less power is needed for circulating the heat transfer fluid and less power is needed to the heater to maintain the desired processing chamber temperature.

The flow rate of the heat transfer fluid can be carefully controlled using, for example, a flow control valve or a variable pump motor that adjusts the pump discharge rate to generate a flow rate that, in combination with one or more heating elements, maintains a constant temperature in the processing chamber.

Although the remaining disclosure will describe the innovative technologies in the context of a particular type of plasma-based processing chamber using the disclosed technology, it will be readily understood that the systems and methods are equally applicable to a variety of other types of plasma-based substrate processing chambers. Accordingly, the technology should not be considered to be so limited as for use with the described etch-based processing alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example processing chamber.

FIG. 2 shows a schematic diagram of an example heat transfer loop for an electrostatic chuck in a plasma-based processing system.

FIGS. 3A and 3B show schematic cross-sectional views of an example thermal control during an active processing stage and an idle stage.

FIG. 4 is a flow diagram of an example process for providing thermal control.

Like reference numbers and designations in the various drawings indicate like elements.

### DETAILED DESCRIPTION

The present specification describes technologies for thermal control of a semiconductor processing chamber. Prior to an initial operation of the processing chamber, or during idle times, heating elements can be used to heat the chamber to a desired operating temperature. During operation of the semiconductor processing chamber, heat is generated, e.g., by a plasma ignited within the chamber. To maintain the operating temperature within a specified range, a heat transfer fluid is circulated to remove excess heat from the chamber or from the substrate in which the operation of the processing chamber is being performed.

In particular, by controlling both a flow rate of a circulating thermal transfer fluid and heating element output, the temperature of the processing chamber can be maintained within a specified temperature range during processing operations as well as during idle or sleep modes. Controlling the flow rate of the heat transfer fluid allows for the temperature to be maintained in a more energy efficient manner. The flow rate can be controlled, for example, by using a flow regulating valve on the incoming heat transfer fluid line or by controlling the discharge rate of a pump used to circulate the heat transfer fluid, e.g., an inverter-controlled pump. While this specification illustrates techniques in the context of a plasma-based processing chamber, the techniques can also be applied to other processing chambers in which a variable heat load is generated.

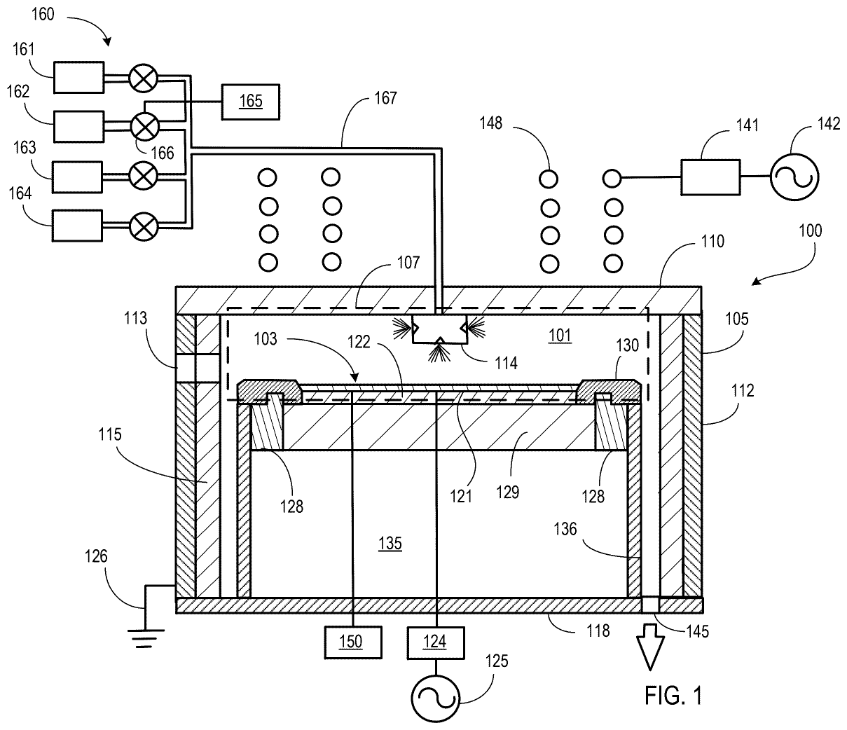

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more vacuum pumps and throttle valves that output gasses and processing byproducts to a foreline vent.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include one or more heating elements disposed within the ESC 122 and connected to a power source for heating the substrate, while a cooling base 129 supporting the ESC 122 can include conduits in a particular geometry for circulating a heat transfer fluid to maintain a temperature of the ESC 122 and substrate 103 disposed thereon. The ESC 122 can be configured to perform in a temperature range required by the thermal budget of the device being fabricated on the substrate 103.

A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves and other components to control the flow of the process gases from the sources. Valves 166 can control the flow of the process gases from the gas sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers.

The lid 110 can incorporate a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. The operation of the power supply 142 can be controlled by a controller, such as controller 165, that also controls the operation of other components in the plasma processing chamber 100.

While an inductively coupled plasma source is illustrated by FIG. 1, the general chamber and heat transfer coolant flow control can be used with other types of plasma sources including, for example, a capacitively coupled plasma source.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100. In some implementations, the controller 165 controls the flow rate of a heat transfer fluid circulating, for example, through the cooling plate of the ESC. For example, as described below, the change in flow rate may be triggered by changes in the processing mode of the processing chamber. Changes in the processing mode may be based on the particular processing operation performed on the substrate as controlled by the controller 165.

In some implementations, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

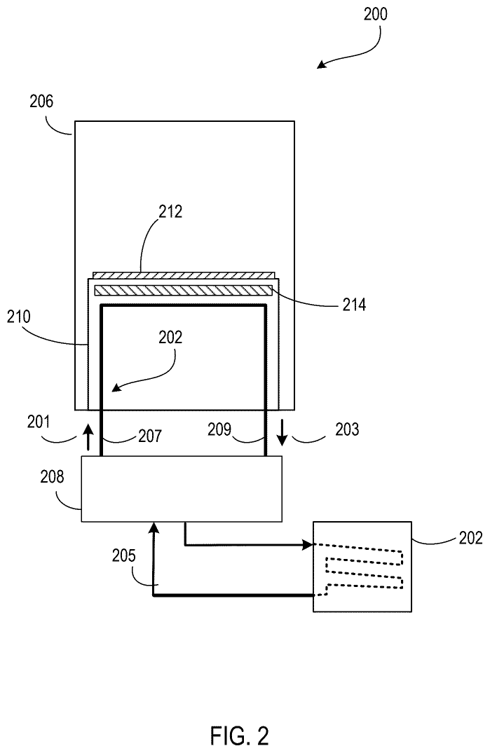

FIG. 2 shows a schematic diagram 200 of an example heat transfer loop 202 for an electrostatic chuck in a plasma-based processing chamber 206. The heat transfer loop includes a heat transfer fluid “in” path 201 and a heat transfer fluid “out” path 203.

The heat transfer fluid “in” path 201 begins with a fluid line 205 exiting a heat exchanger 202 for passing the heat transfer fluid. In some implementations, the heat transfer fluid exiting the heat exchanger 202 has a temperature corresponding to a specified temperature for maintaining a particular processing chamber temperature. The temperature of the heat transfer fluid can be, for example, 65 degrees or 90 degrees Celsius.

The heat exchanger 202 receives heat transfer fluid at an input port and outputs heat transfer fluid having a specific temperature at an output port coupled to the fluid line 205. The heat exchanger 202 can be, for example, a chamber that allows heat to pass between the heat transfer fluid and another heat transfer fluid within the heat exchanger 202 without the two fluids coming into direct contact. For example, the chamber can have a path that carries the heat transfer fluid from the input port to the output port. The chamber can also include a second heat transfer fluid that circulates through the chamber and around the path. Heat is exchanged to achieve a desired output temperature of the heat transfer fluid. To maintain the desired temperature, a chamber body of the processing chamber includes a fluid path through which a heat transfer fluid continuously circulates, e.g., to remove excess heat generated by the plasma processing. The heat transfer fluid can be selected according to particular performance parameters such as an ability to operate in particular temperature ranges and chemical stability. The heat transfer fluid can be, for example, a fluorinated fluid such as perfluoropolyether including Galden® PFPE.

The fluid line 205 is coupled to a flow control module 208. The flow control module 208 can include equipment for managing a flow rate of the circulating heat transfer fluid. For example, the equipment can include one or more pumps and/or one or more flow valves. Consequently, the flow rate can be controlled, for example, to provide a first flow rate during a processing mode of the processing chamber and a second flow rate during an idle or sleep mode of the processing chamber.

In some implementations, the flow rate is controlled using a variable speed pump, or an inverter-controlled pump. The inverter adjusts the frequency of the pump motor to control the revolution per minute of the pump, thereby setting the flow rate to a given setpoint based on the frequency. The inverter-controlled pump allows for the change in flow rate to be electronically controlled based, for example, on a signal indicating a change in the processing mode of the processing chamber. Thus, the setpoint of the pump can be changed, for example from a first setpoint to a second setpoint, in response to a change in the mode from a first mode corresponding to an active processing operation to a second mode corresponding to an idle or sleep state. Another change in the mode, e.g., from the second mode back to the first mode, may cause the setpoint to change back from the second setpoint to the first setpoint.

In some implementations, the flow rate is controlled using valves. For example, a proportional-integral-derivative (PID) controlled flow regulating valve positioned in the flow line to the processing chamber can be adjusted to control the flow rate of the heat transfer fluid into the processing chamber. In some implementations, the PID valve, in response to an electronic signal, adjusts a pressure on a structure in the valve (e.g., a diaphragm) that constricts or expands the fluid flow through the valve. The signal can be triggered, for example, based on a change in the mode of the processing chamber. Specific pressure setpoints can be determined for each mode of the processing chamber in a similar manner as described above with respect to the inverter-controlled pump.

Flow rate setpoints can be predetermined, for example, based on testing or historical data to provide the desired amount of heat transfer. For example, in some implementations, a first setpoint during a processing mode of the processing chamber, provides a flow rate of ten gallons per minute. However, during an idle or sleep mode, a second setpoint can reduce the flow rate to five gallons per minute. The actual flow rates for the first and second setpoints can vary depending on the desired temperature to maintain, surface area of the fluid path within the processing chamber, the type of heat transfer fluid used, etc. In addition, the flow rate can change discretely, e.g., from the first flow rate to the second, or can gradually ramp up or ramp down between the setpoints.

In some implementations, the fluid line is also coupled to a facility box, for example, for the plasma based processing system. The facility box provides a manifold for connecting components of the plasma-based processing system to external components. Thus, for example, the facility box allows for the coupling of the fluid line to the plasma-based processing system. For example, the heat exchanger 202 may thus be separate from the plasma processing system. In some alternative implementations, the heat exchanger can be integrated within the plasma-based processing system so that the facility box is not necessary to couple the fluid line to the heat exchanger.

Fluid line 207 exits the flow control module 208 and is input into the processing chamber 206. The processing chamber 206 can be, for example, similar to processing chamber 100 of FIG. 1. In some implementations, the processing chamber 206 is heated or cooled by the heat transfer fluid to maintain a particular chamber temperature, e.g., 65 or 90 degrees Celsius. In particular, in the example heat transfer loop 200, the heat transfer fluid circulates through the electrostatic chuck 210 near a surface of the ESC supporting the substrate 212, e.g., a wafer, on which the plasma processing operation is being performed. Within the ESC, for example within a cooling plate of the ESC, the heat transfer fluid may follow various paths, not illustrated. The paths can be configured, for example, to provide particular heat transfer characteristics with respect to the substrate 212 or the chamber processing region.

The ESC can further include one or more heating elements 214. The one or more heating elements 214 can correspond to one or more resistive heaters that convert electrical energy into heat energy, which can be used to heat the substrate 212.

The fluid “out” path 203 begins with heat transfer fluid exiting the processing chamber 206 and into fluid line 209. The fluid line 209 may pass through the flow control module 208 or may pass directly to the input of the heat exchanger 202 completing a heat transfer loop, e.g., as a closed loop system.

In some implementations, there may be other heat transfer loops. For example, while FIG. 2 illustrates a fluid path through the ESC, other fluid paths may provide heat transfer to the processing chamber through the chamber side walls. In such implementations, a heat transfer fluid flow rate can be similarly controlled according to the chamber processing mode.

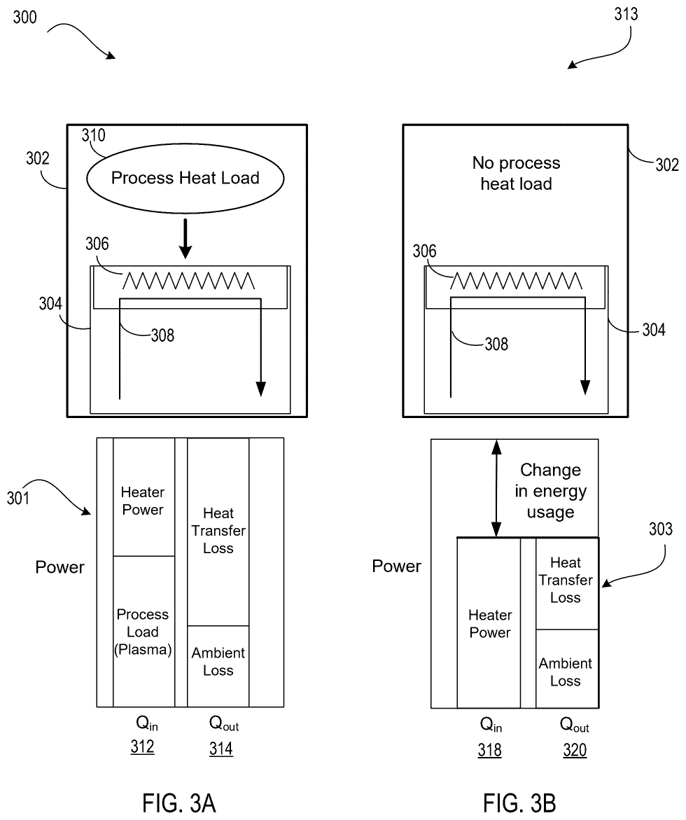

FIGS. 3A and 3B show schematic cross-sectional representations of example thermal controls during an active processing stage and an idle stage. FIGS. 3A and 3B represent simplified plasma processing chambers for purposes of illustrating the changes in flow control on energy usage.

FIG. 3A shows a schematic cross-sectional representation 300 of the plasma processing chamber 302 during an active processing mode. FIG. 3A further includes chart 301 illustrating the power needed to maintain a particular heat balance.

In FIG. 3A, the plasma processing chamber 302 includes a substrate support 304 that includes one or more heating elements 306 and a heat transfer fluid line 308.

During the active processing mode, a process heat load 310 is generated within the chamber. However, during processing, the temperature of the substrate (not shown) resting on the substrate support 304 needs to be maintained within a specified tolerance. The substrate temperature is maintained whether the processing chamber 302 is in the active processing mode or in an idle/sleep mode. Idle and sleep modes can be described as a non-processing mode of the processing chamber 302 in which the processing chamber 302 is maintained in a state ready to enter the active processing mode within a specified time frame. The process heat load 310 applied to the substrate can vary during the active processing mode, for example, based on the applied RF power.

To regulate the substrate temperature during the active processing mode, the heat transfer fluid circulating through the heat transfer fluid line 308 can remove heat energy, e.g., by absorbing heat energy into the heat transfer fluid, which is then output from the processing chamber. As an example, in FIG. 3A, the flow rate of the heat transfer fluid can be 10 gallons per minute.

Additionally, the one or more heating elements 306 can be controlled to adjust the temperature. For example, the one or more heating elements 306 can be resistive heaters. A PID control controller can be used to adjust the heating power of the one or more heating elements 306 based on temperature monitoring.

In some implementations, as the RF load changes, the flow rate can by dynamically adjusted. In particular, the amount of heat added to the substrate can depend on the amount of RF load during processing operations. The flow rate can be adjusted more incrementally than just between a first setpoint and a second setpoint. For example, an inverter based pump that adjusts the pump speed to control the flow rate can reduce the flow by a determined amount in response to a reduction in the RF load. Similarly, the flow can be increased with increase RF load. The amount and speed of the flow rate changes can be determined experimentally based on processing chamber operations and substrate temperature measurements.

The chart 301 illustrates the heat balance on the substrate during the active processing operation. The heat balance indicates that the total heat load applied on the substrate is equal to the total heat load removed from the processing chamber. In particular, a first stacked bar 312 represents the heat load applied on the substrate Qᵢₙ, which is composed of the heater power and the process heat load. A second stacked bar 314 represents the heat load removed from the substrate Qₒᵤₜ, which is composed of an ambient loss (e.g., radiated from the processing chamber or exhausted from the vacuum pumps) and the heat removed by the circulating heat transfer fluid.

FIG. 3B shows a schematic cross-sectional representation 316 of the plasma processing chamber 302 during an idle or sleep mode. FIG. 3A further includes a chart 318 illustrating the power needed to maintain a particular heat balance.

In FIG. 3B, the plasma processing chamber 302 includes the substrate support 304 that includes the one or more heating elements 306 and the heat transfer fluid line 308. During an idle or sleep mode, there is no process heat load in the processing chamber 302. As a result, when the heat transfer fluid flow rate is held constant, the heat transfer fluid has a greater capacity to absorb heat load from the substrate. However, this can mean that the heat transfer fluid carries away too much heat, which would lead to the temperature of the substrate dropping below the tolerance level. To correct for this, the power provided to one or more of the heating elements can be increased to maintain the heat balance.

However, when the flow rate of the heat transfer fluid through the heat transfer fluid line 308 can be controlled, the amount of heat absorbed by the heat transfer fluid can be reduced. As an example, FIG. 3B illustrates a change in the heat transfer fluid flow rate from ten gallons per minute to five gallons per minute. The actual flow rates before and after can vary according to different factors including the particular heat transfer fluid used and the characteristics of the processing chamber.

The chart 303 illustrates the heat balance on the substrate during the idle or sleep mode. In particular, a first stacked bar 318 represents the heat load applied on the substrate Qᵢₙ, which without the process heat load, is solely due to the heater power. A second stacked bar 320 represents the heat load removed from the substrate Qₒᵤₜ, which is composed of the ambient loss and the heat removed by the circulating heat transfer fluid.

However, because the overall head load is less, the heat balance can be maintained by reducing the amount of heat transferred out of the processing chamber by the heat transfer fluid. In particular, by reducing the flow rate, not only is less energy used to circulate the heat transfer fluid, less energy is needed to power the one or more heating elements. This results in an overall energy savings during the idle and sleep modes.

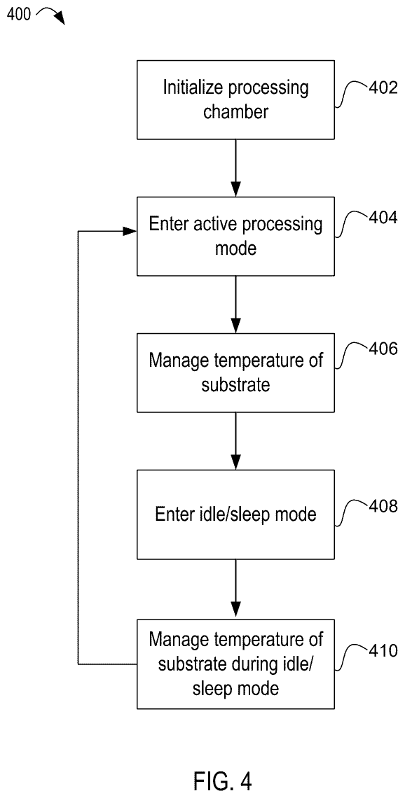

FIG. 4 is a flow diagram of an example process for providing thermal control. For convenience, the process 400 will be described with respect to a system that performs the process 400, e.g., a cooling and heating system for a plasma-based processing system, for example, as managed by control 165 of FIG. 1.

The system initializes the processing chamber (402). The initialization can include, for example, activating the one or more heating elements to bring the chamber, and in particular a substrate, to a particular operating temperature range.

The system enters an active processing mode (404). The active processing mode can include performing a semiconductor fabrication operation on the substrate using plasma based processing.

The system manages the temperature of the substrate during the active processing operation to keep the temperature of the substrate within the operating temperature range (406). The temperature management can include circulating a heat transfer fluid at a particular first flow rate to remove heat from the processing chamber and adjusting a power supplied to one or more heating elements to keep the substrate temperature within the operating temperature range.

The system enters an idle/sleep mode (408). In response to a signal indicating, for example, a pause in processing, the plasma is discontinued within the processing chamber.

The system manages the temperature of the substrate during the idle/sleep mode to keep the temperature of the substrate within the operating temperature range (410). The temperature management can include signaling flow control structures to reduce the flow of the heat transfer fluid. For example, this can include changing a setpoint of a flow control valve or a fluid pump to reduce the heat transfer fluid flow rate by a specified amount. The heating elements can then be adjusted as needed to maintain the substrate temperature within the operating range.

The system can alternate between the active processing mode and the idle/sleep mode. Each change in mode can trigger corresponding adjustments to the flow rate of the heat transfer fluid, e.g., increasing the flow rate when switching from the idle mode to the active processing mode to a predefined setpoint. Thus, the operations 404 to 410 can repeat as the mode of the processing chamber cycles between active and idle or sleep modes.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system comprising:
a processing chamber, the processing chamber comprising:
a chamber volume, and
a substrate support positioned within the chamber volume, the substrate support comprising a fluid path configured to circulate a heat transfer fluid within a body of the substrate support; and
a flow control module configured to adjust a flow rate of the heat transfer fluid circulating through the body of the substrate support according to a processing heat load applied to the substrate by the processing chamber.

2. The system of claim 1, the substrate support comprising a first surface facing upon which a substrate is positioned during a processing operation and one or more heating elements arranged within a body of the substrate support between the first surface and the fluid path.

3. The system of claim 1, wherein the flow control module comprises an inverter pump configured to dynamically adjust a flow rate by adjusting a speed of the pump motor.

4. The system of claim 1, wherein the flow control module comprises a PID flow control valve having a first setpoint and a second setpoint configured to provide respective specified flow rates.

5. The system of claim 1, wherein the flow of the heat transfer fluid is reduced during a non processing mode of the processing chamber while maintaining a substrate temperature within a specified operating temperature range.

6. The system of claim 1, wherein the substrate support comprises an electrostatic chuck.

7. The system of claim 1, further comprising one or more fluid lines coupling the heat transfer fluid output of the substrate support to a heat exchanger and one or more fluid lines coupling the heat exchanger to an input of the substrate support, wherein the collection of fluid lines completes a heat transfer loop.

8. A method comprising:
initializing a processing chamber to perform a plurality of processing operations, the initializing comprising heating the chamber to a temperature within a specified range for performing the processing operation;
executing a first processing operation at a first RF energy, wherein during the first processing operation a heat transfer fluid is circulated in the chamber at a first flow rate configured to remove heat energy from the chamber; and
upon completion of the first processing operation, changing an RF energy level from the first RF energy level to a second RF energy level, wherein in response to changing the RF energy level,
changing the flow rate of the heat transfer fluid from a first flow rate to a second flow rate.

9. The method of claim 8, wherein changing the flow rate for the heat transfer fluid comprises reducing the flow rate, thereby reducing an amount of heat removed from the processing chamber.

10. The method of claim 8, wherein the changing of the RF energy level comprises a changing a processing mode from a first active mode to an idle mode, wherein in the idle mode the RF energy level is zero.

11. The method of claim 8, wherein the initializing comprises applying energy to one or more heating elements to heat the processing chamber.

12. The method of claim 11, wherein the temperature of the processing chamber is maintained within the specified range during the idle mode, the maintaining including adjusting the one or more heating elements.

13. The method of claim 8, further comprising combining contributions of the heat transfer fluid and one or more heating elements to maintain a heat balance in the chamber, wherein reducing the flow rate of the heat transfer fluid allows for the heat balance to be maintained with a reduced overall energy input.

14. The method of claim 8, further comprising receiving a signal at a controller when the RF energy level changes and, in response, changing the flow rate accordingly.

15. A substrate support of a processing chamber comprising:
one or more embedded electrodes configured to provide electrostatic attraction of a substrate;
one or more heating elements; and
one or more fluid paths configured to circulate a heat transfer fluid through the substrate support, the heat transfer fluid having a variable flow rate according to a processing mode of the processing chamber.

16. The substrate support of claim 15, the substrate support comprising a first surface facing the interior of a chamber volume, wherein the one or more heating elements and fluid paths positioned proximate to the first surface.

17. The substrate support of claim 16, wherein the one or more heating elements are positioned between the first surface and the fluid paths.

18. The substrate support of claim 15, wherein the one or more heating elements are arranged within a body of the substrate support and configured to heat at least a portion of a surface of the substrate when the substrate is retained.

19. The substrate support of claim 15, wherein the fluid paths are configured to circulate a heat transfer fluid at different flow rates to remove excess heat from the substrate during a semiconductor fabrication operation.

20. The substrate support of claim 15, wherein the substrate support comprises an electrostatic chuck.
